(19) United States
(12) Patent Application Publication
(10) Pub. No.: US 2026/0029462 A1
(43) Pub. Date: Jan. 29, 2026

(54) SEMICONDUCTOR PACKAGE HEAT GENERATION SIMULATION UNIT FOR CHECKING HEAT DISTRIBUTION OF BURN-IN BOARD AND METHOD FOR ACQUIRING HEAT DISTRIBUTION OF BURN-IN BOARD USING THE SAME

(71) Applicant: TFE CO., LTD., Gyeonggi-do (KR)

(72) Inventor: Sung Jue MOON, Gyeonggi-do (KR)

(73) Assignee: TFE CO., LTD., Gyeonggi-do (KR)

(21) Appl. No.: 18/865,862

(22) PCT Filed: Nov. 14, 2023
(86) PCT No.: PCT/KR2023/018300

§ 371 Date: Nov. 14, 2024

(30) Foreign Application Priority Data
May 23, 2023 (KR) 10-2023-0066459

(51) Int. Cl. G01R 31/28; G01R 1/04

(52) U.S. Cl. CPC G01R 31/2863; G01R 1/0458; G01R 31/2875; G01R 31/2896

(57) ABSTRACT

Provided are a semiconductor package heat generation simulation unit for checking heat distribution of a burn-in board and a method for acquiring heat distribution of a burn-in board using the same, the unit including: a circuit board including input/output terminals each corresponding to a conductive part of a socket of the burn-in board, and a power terminal and a signal terminal, connected to the input/output terminals; a heater configured to generate heat by power input through the power terminal; and a temperature sensor configured to measure a temperature of heat generated by the heater and output temperature information on the temperature through the signal terminal.

### TECHNICAL FIELD

The present invention relates to a semiconductor package heat generation simulation unit for checking heat distribution of a burn-in board and a method for acquiring heat distribution of a burn-in board using the same.

### BACKGROUND ART

In general, a semiconductor package completed through a semiconductor manufacturing process may be shipped in a case where the package is classified as a good product after being checked through a test (inspection) process to confirm if its operation feature is properly implemented.

In this test process, a test may be performed by connecting the semiconductor package to a socket to check whether there are any problems with its electrical operation. A test may also be performed in an environment where the semiconductor package is heated and subjected to a temperature stress.

The environment where the semiconductor package is heated is required to prevent an excessive temperature stress to the semiconductor package. To this end, it is necessary to acquire information on the environment and improve the environment based on the information.

The above-mentioned background describes technical information possessed for deriving embodiments of the present invention or acquired during a derivation process, by an inventor, and cannot necessarily be considered as known technology disclosed to a general public before this application.

### DISCLOSURE

### Technical Problem

An object of the present invention is to provide a semiconductor package heat generation simulation unit for checking heat distribution of a burn-in board that is capable of simulating the heat distribution generated in a semiconductor package in a test environment for the semiconductor package accommodated in the burn-in board, and a method for acquiring heat distribution of a burn-in board using the same.

Another object of the present invention is to provide a semiconductor package heat generation simulation unit for checking heat distribution of a burn-in board that is capable of acquiring the heat distribution of the burn-in board by using a configuration for testing an actual semiconductor package as it is without any change, and a method for acquiring heat distribution of a burn-in board using the same.

### Technical Solution

According to an aspect of the present invention, provided is a semiconductor package heat generation simulation unit for checking heat distribution of a burn-in board, the unit including: a circuit board including input/output terminals each corresponding to a conductive part of a socket of the burn-in board, and a power terminal and a signal terminal, connected to the input/output terminals; a heater configured to generate heat by power input through the power terminal; and a temperature sensor configured to measure a temperature of heat generated by the heater and output temperature information on the temperature through the signal terminal.

The unit may further include a molding coupled to the circuit board while surrounding the heater and the temperature sensor.

The circuit board may have a size corresponding to that of a semiconductor package tested in the socket.

The heater may include a surface heating element having a size corresponding to that of the circuit board.

The heater may include an opening exposing the signal terminal.

The temperature sensor may be disposed in the opening while connected to the signal terminal.

According to another aspect of the present invention, provided is a method for acquiring heat distribution of a burn-in board, the method including: disposing the semiconductor package heat generation simulation unit described above in a socket of the burn-in board; supplying power to input/output terminals through the socket; and receiving temperature information on a temperature measured by a heater based on heat generated by the heater through the input/output terminals and the socket.

The method may further include outputting the temperature information on a screen for each socket of the burn-in board.

### Advantageous Effects

As set forth above, according to the semiconductor package heat generation simulation unit for checking heat distribution of a burn-in board and the method for acquiring heat distribution of a burn-in board using the same according to the present invention, the heater and the temperature sensor may be connected to the circuit board electrically connected to the socket of the burn-in board, thus allowing the temperature information based on heat generated by the heater to be measured by the temperature sensor and output to the outside. Therefore, the heat distribution generated in the semiconductor package may be simulated during the test of the semiconductor package accommodated in the burn-in board.

In addition, the heat generation simulation unit may function as the semiconductor package by replacing the actual semiconductor package being tested, thus allowing the socket, the test board, or the like used for the normal test of the semiconductor package to be used as it is when checking the heat distribution. Therefore, there is no need to change existing equipment or facilities or to install new equipment or the like for checking the heat distribution.

### DESCRIPTION OF DRAWINGS

FIG. 1 is a cross-sectional view showing a semiconductor package heat generation simulation unit 100 for checking heat distribution of a burn-in board according to an embodiment of the present invention.

FIG. 2 is an exploded perspective view of the semiconductor package heat generation simulation unit 100 of FIG. 1.

FIG. 3 is a flow chart for describing a method for acquiring heat distribution of a burn-in board according to another embodiment of the present invention.

FIG. 4 is a perspective view showing a situation where the semiconductor package heat generation simulation unit 100 is disposed on a burn-in board BB in relation to a step S1 of FIG. 3.

FIG. 5 is an image diagram showing temperature information of the burn-in board that is output on a screen in relation to another step S7 of FIG. 3.

### DETAILED DESCRIPTION

Hereinafter, embodiments of the present invention are described in detail with reference to the accompanying drawings.

The present invention is not limited to the embodiments described below, may be variously modified, and may be implemented in various forms. These embodiments are provided only to make the present invention complete and allow those skilled in the art to completely appreciate the scope of the present invention. Therefore, it should be understood that the present invention is not limited to the embodiments disclosed below, includes substitution or addition of a configuration in one embodiment with or to a configuration in another embodiment, as well as all modifications, equivalents, or substitutions, included in the spirit and scope of the present invention.

It should be understood that the accompanying drawings

are provided only to allow the embodiments of the present invention to be easily understood, and the spirit of the present invention is not limited to the accompanying drawings, and includes all the modifications, equivalents, and substitutions included in the spirit and scope of the present invention. In consideration of convenience of understanding, the size or thickness of a component may be expressed exaggeratedly large or small in the drawings, and the scope of the present invention should not be interpreted as being limited due to this expression.

Terms used in the specification are used only to describe the specific implementation examples or embodiments rather than limiting the present invention. In addition, a term of a singular number may include its plural number unless explicitly indicated otherwise in the context. Terms “include”, “have”, and the like used in the specification specify the presence of features, numerals, steps, operations, components, parts, or combinations thereof, mentioned in the specification. That is, it should be understood that the term “include” or “have” does not preclude the presence or addition of one or more other features, numerals, operations, components, parts, or combinations thereof, which is mentioned in the specification.

Terms including ordinal numbers such as “first” or “second” may be used to describe various components. However, these components are not limited to these terms. These terms are used only to distinguish one component and another component from each other.

It should be understood that when one component is referred to as being “connected to” or “coupled to” another component, one component may be directly connected or coupled to another component, or may be connected or coupled to another component while having a third component interposed therebetween. On the other hand, it should be understood that when referred to as being “directly connected to” or “directly coupled to” another element, one element may be connected or coupled to another element without a third element interposed therebetween.

It should be understood that when an element is referred to as being “on” or “below” another element, the element may be “directly on” another element, or may have a third element interposed therebetween.

Unless defined otherwise, it should be understood that all the terms including technical and scientific terms, used herein, have the same meanings as those generally understood by those skilled in the art to which the present invention pertains. Terms generally used and defined by a dictionary should be interpreted as having the same meanings as meanings within a context of the related art, and should not be interpreted as having ideal or excessively formal meanings unless the corresponding terms are clearly defined otherwise in the present application.

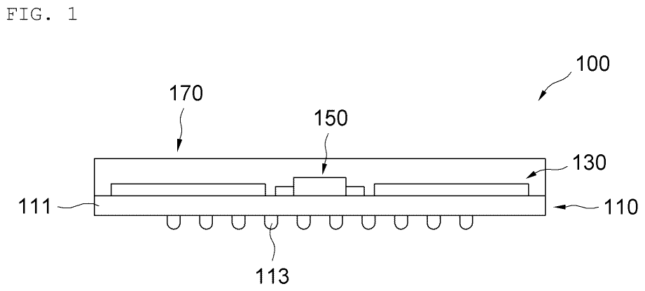

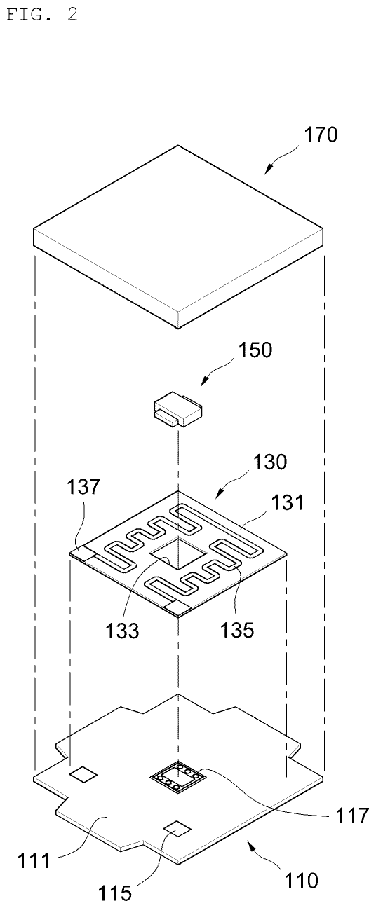

FIG. 1 is a cross-sectional view showing a semiconductor package heat generation simulation unit 100 for checking heat distribution of a burn-in board according to an embodiment of the present invention, and FIG. 2 is an exploded perspective view of the semiconductor package heat generation simulation unit 100 of FIG. 1.

Referring to the drawings, the semiconductor package heat generation simulation unit 100 may include a circuit board 110, a heater 130, a temperature sensor 150, and a molding 170.

The circuit board 110 may have a board body 111 on which a conductive circuit is printed on an insulating material. The board body 111 may generally have a square plate shape. Input/output terminals 113 may be formed on the bottom of the board body 111. A power terminal 115 and a signal terminal 117 may be formed on an upper surface of the board body 111.

The heater 130 may be a surface heating element having a size corresponding to that of the circuit board 110. In detail, the heater 130 may have a base plate 131 stacked on an upper surface of the circuit board 110. The base plate 131 is an insulator and may have a slightly smaller area than the board body 111. An opening 133 may be formed in the base plate 131. The opening 133 may be a through space formed in the center of the base plate 131, for example, and expose the signal terminal 117. The heater 130 may also have a resistance wire 135 and an input terminal 137. The resistance wire 135 may generate heat by power input through the input terminal 137. The resistance wire 135 may be made of a metal material, for example, steel use stainless (SUS). An insulating film may be disposed on the lower or upper side of the resistance wire 135. The insulating film may form the base plate 131.

The temperature sensor 150 may be a component for measuring a temperature based on heat generated by the heater 130, and output the temperature information, which is information on the temperature. The temperature sensor 150 may be disposed in the opening 133 while connected to the signal terminal 117. The temperature information may be output through the signal terminal 117. The signal terminal 117 may also function as a power supply to the temperature sensor 150 in addition to outputting the temperature information.

The molding 170 may be a component coupled to the circuit board 110 to surround the heater 130 and the temperature sensor 150. The molding 170 may be a cured insulating molten resin. The molding 170 may protect the heater 130 and the temperature sensor 150 from an external environment and limit a loss of heat generated by the heater 130. In this way, the temperature sensor 150 may acquire the temperature information more reliably.

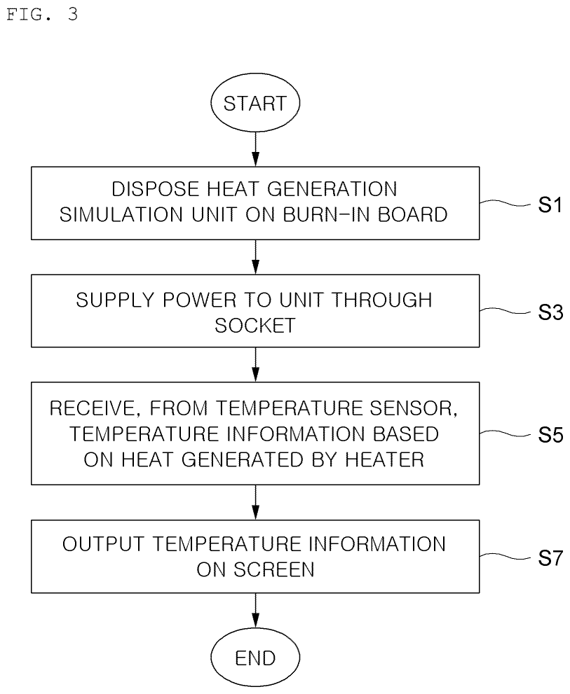

A method for acquiring heat distribution of a burn-in board using the semiconductor package heat generation simulation unit 100 described above is described with reference to FIGS. 3 to 5.

FIG. 3 is a flow chart for describing the method for acquiring heat distribution of a burn-in board according to another embodiment of the present invention.

Referring further to this drawing, the method may first include disposing the semiconductor package heat generation simulation unit 100 on a burn-in board for acquiring heat distribution (S1).

The method may include supplying, by a test board (controller), power to input/output terminals 113 through a socket of the burn-in board (S3). Power may be provided to a heater 130 through a power terminal 115 and also to a temperature sensor 150 through a signal terminal 117.

A resistance wire 135 of the heater 130 may be heated by input power. Accordingly, the temperature sensor 150 may measure a temperature of heat generated by the heater 130 and output temperature information thereon. The temperature information may be output through the signal terminal 117 and the socket. Through this configuration, the method may include receiving, by the controller, the temperature information (S5).

The method may include visually outputting, by the controller, the temperature information (S7). The temperature information may be expressed as a number or a color.

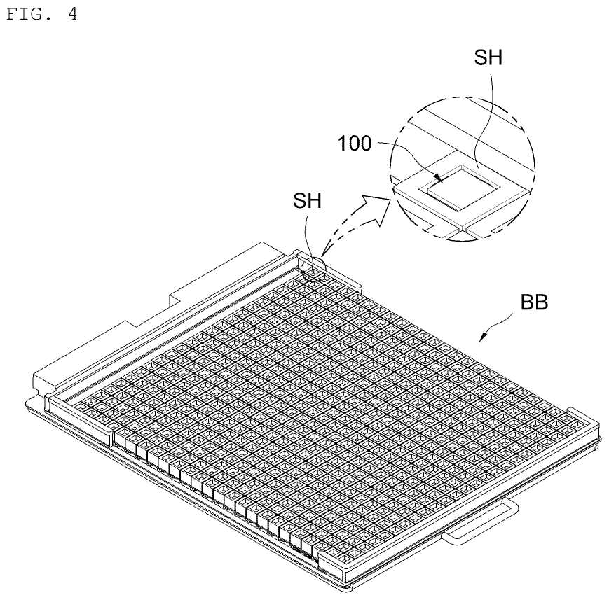

FIG. 4 is a perspective view showing a situation where the semiconductor package heat generation simulation unit 100 is disposed on a burn-in board BB in relation to a step S1 of FIG. 3.

Referring further to this drawing, a number of socket housings SH may be arranged in a grid pattern on the burn-in board BB. The socket housing SH may be formed to accommodate a semiconductor package. The socket may be disposed at the bottom of the socket housing SH. The socket may have a conductive part to thus be electrically connected to the test board.

The semiconductor package heat generation simulation unit 100 may replace the semiconductor package disposed in the socket housing SH in an actual test. In this way, the semiconductor package heat generation simulation unit 100 may be accommodated in the socket housing SH and connected to the socket.

To this end, the input/output terminals 113 may each be formed to correspond to the conductive part of the socket. In addition, the circuit board 110 may have a size (width) corresponding to that of the semiconductor package.

Through this configuration, an existing burn-in test facility for the semiconductor package (e.g., burn-in board BB or test board) may be used for the heat generation simulation using the semiconductor package heat generation simulation unit 100 without any change.

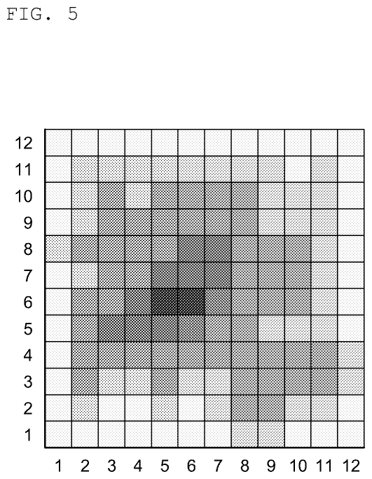

FIG. 5 is an image diagram showing the temperature information of the burn-in board that is output on a screen in relation to another step S7 of FIG. 3. For simplicity, this drawing shows only the temperature information for a portion of the socket housing SH of the burn-in board BB.

Referring further to this drawing, the temperature information for each socket housing (or the socket) may be acquired as the semiconductor package heat generation simulation unit 100 is input to each socket housing SH.

The temperature information may correspond to each socket being in a grid arrangement to thus also be displayed on the screen in the grid arrangement. The temperature information may also be distinguished by a shade of color, as exemplified.

Based on this heat distribution, the burn-in test facility for the semiconductor package may be improved for the semiconductor packages to be tested under appropriate heat distribution.

### INDUSTRIAL APPLICABILITY

The present invention has industrial applicability in a field of manufacturing a semiconductor test board.

1. A semiconductor package heat generation simulation unit for checking heat distribution of a burn-in board, the unit comprising:
a circuit board including input/output terminals each corresponding to a conductive part of a socket of the burn-in board, and a power terminal and a signal terminal, connected to the input/output terminals;
a heater configured to generate heat by power input through the power terminal; and
a temperature sensor configured to measure a temperature of heat generated by the heater and output temperature information on the temperature through the signal terminal.

2. The unit of claim 1, further comprising a molding coupled to the circuit board while surrounding the heater and the temperature sensor.

3. The unit of claim 1, wherein the circuit board has a size corresponding to that of a semiconductor package tested in the socket.

4. The unit of claim 1, wherein the heater includes a surface heating element having a size corresponding to that of the circuit board.

5. The unit of claim 1, wherein the heater includes an opening exposing the signal terminal.

6. The unit of claim 5, wherein the temperature sensor is disposed in the opening while connected to the signal terminal.

7. A method for acquiring heat distribution of a burn-in board, the method comprising:
disposing the semiconductor package heat generation simulation unit according to claim 1 in a socket of the burn-in board;
supplying power to input/output terminals through the socket; and
receiving temperature information on a temperature measured by a heater based on heat generated by the heater through the input/output terminals and the socket.

8. The method of claim 7, further comprising outputting the temperature information on a screen for each socket of the burn-in board.
